(19) United States
(12) Patent Application Publication
(10) Pub. No.: US 2019/0249122 A1
(43) Pub. Date: Aug. 15, 2019

(54) RINSING AGENT COMPOSITION FOR SILICON WAFERS

(71) Applicant: KAO CORPORATION, Tokyo (JP)

(72) Inventor: Yohei UCHIDA, Wakayama (JP)

(73) Assignee: KAO CORPORATION, Tokyo (JP)

(21) Appl. No.: 16/345,444

(22) PCT Filed: Oct. 26, 2017
(86) PCT No.: PCT/JP2017/038767

§ 371 Date: Apr. 26, 2019

(30) Foreign Application Priority Data
Oct. 28, 2016 (JP) 2016-211924
Oct. 25, 2017 (JP) 2017-206437

(51) Int. Cl. C11D 11/00; C11D 1/72; C11D 1/00; C11D 1/16; C09G 1/02; H01L 21/306; H01L 21/02; B08B 3/08

(52) U.S. Cl. CPC C11D 11/0047; C11D 1/72; C11D 1/008; B08B 3/08; C09G 1/02; H01L 21/30625; H01L 21/02057; C11D 1/16

(57) ABSTRACT

The rinsing composition for a silicon wafer of the present invention is a rinsing composition for a silicon wafer containing a water-soluble polymer and water. The water-soluble polymer exhibits a difference (Z−Z₀) between a zeta-potential Z of a water-soluble polymer-containing silica aqueous dispersion (aqueous dispersion S) and a zeta-potential Z₀ of a silica aqueous dispersion (aqueous dispersion S₀) of 25 mV or less. The aqueous dispersion S consists of the water-soluble polymer, silica particles, water, and as needed, hydrochloric acid or ammonia, and has a concentration of the water-soluble polymer of 0.1 mass %, a concentration of the silica particles of 0.1 mass %, and a pH of 7.0 at 25° C. The aqueous dispersion S₀ consists of silica particles, water, and as needed, hydrochloric acid or ammonia, and has a concentration of the silica particles of 0.1 mass %, and a pH of 7.0 at 25° C.

### TECHNICAL FIELD

The present invention relates to a rinsing composition for a silicon wafer, a method for rinsing a silicon wafer using the same, and a method for producing a silicon wafer and a method for producing a semiconductor substrate using the same.

### BACKGROUND ART

Recently, the design rule for semiconductor devices have become more minute due to the increasing demand for the trend of higher recording capacity of a semiconductor memory. As a result, in a photolithography carried out in the process of manufacturing the semiconductor device, the depth of focus is decreased, and the demand for the reduction in the surface defects (LPD: light point defects) and surface roughness (haze) of a silicon wafer (bare wafer) has become even further strict.

In order to improve the quality of a silicon wafer, a polishing step for polishing a silicon wafer includes a lapping (rough polishing) step, an etching step and a final polishing step. The lapping step includes planarizing a silicon wafer that has been obtained by slicing a silicon single crystal ingot into thin disks. The etching step includes etching the lapped silicon wafer, and the final polishing step includes mirror-finishing the surfaces of the silicon wafer. Particularly, the final polishing step carried out in the final stage of the polishing aims to reduce the haze and to reduce the LPD such as particles, scratches and pits, which is achieved by improving wettability (bydrophilicity) of the polished silicon wafer surface.

As polishing liquid compositions for polishing a silicon wafer, Patent Document 1 discloses a polishing liquid composition for improving a haze level that contains silica particles, hydroxyethyl cellulose (HEC), polyethylene oxide, and an alkali compound. Patent Document 2 discloses a polishing liquid composition for a silicon wafer for reducing both of the surface roughness (haze) and surface defects (LPD) that contains a water-soluble polymer. In the water-soluble polymer, a ratio of the number of oxygen atoms derived from hydroxyl groups to the number of oxygen atoms derived from polyoxyalkylene (the number of oxygen atoms derived from hydroxyl groups/the number of oxygen atoms derived from polyoxyalkylene) is within a predetermined range. Patent Document 3 discloses a polishing composition for a silicon wafer for reducing the contamination of the surfaces of a polished object while reducing the aggregation of abrasive grains. The polishing composition contains a polyvinyl alcohol resin having a 1,2-diol structure in its side chain and abrasive grains whose surfaces are chemically modified to have a minus zeta-potential on the surfaces in a solution having a pH of 2.0 or more and to have no isoelectric point. Patent Document 4 discloses a polishing composition for a silicon wafer for preventing the deterioration of smoothness and reducing the number of defects. The polishing composition contains hydroxypropylmethylcellulose and abrasive grains, and the abrasive grains have a negative zeta-potential in the polishing composition. Patent Document 5 discloses, though not a polishing liquid composition or used for the surfaces of a silicon wafer, a cleaning liquid for a semiconductor device substrate for removing contaminants on the surfaces of the semiconductor device substrate after CMP processing and cleaning the surfaces of the substrate in a short period of time. The cleaning liquid contains a polymer flocculant selected from polyvinyl pyrrolidone and polyethylene oxide-polypropylene oxide block copolymers, and can reduce the attachment of fine particles to the surfaces of the semiconductor device substrate by increasing the particle diameters of the fine particles by aggregation and making the zeta-potential of the fine particles negative.

### PRIOR ART DOCUMENTS

### Patent Documents

Patent document 1: JP 2004-128089 A
Patent document 2: WO 2015/060293
Patent document 3: WO 2014/084091
Patent document 4: JP 2014-154707 A
Patent document 5: JP 2012-094852 A

### DISCLOSURE OF INVENTION

### Problem to be Solved by the Invention

Under alkaline conditions, the surface charge of silica particles and the surface charge of a silicon wafer are both negative. Owing to charge repulsion, the silica particles cannot approach the silicon wafer, and the polishing rate cannot be fully exhibited. However, a polymer contained in the polishing liquid composition absorbs on both of the surfaces of the silicon wafer and the silica particles and this reduces the charge repulsion between the silica particles and the silicon wafer. Thereby, a binder effect is exhibited and the polishing rate of the silicon wafer improves.

On the other hand, owing to the polymer attached on the surfaces of the silicon wafer that has been polished in a polishing step (hereinafter, also referred to as a “polished silicon wafer”), the silica particles will reattach on the surfaces of the silicon wafer even if the polished silicon wafer is subjected to, e.g., water rinsing that includes supplying water between the polished silicon wafer and a pad, and moving the pad relative to the polished silicon wafer while the silicon wafer is in contact with the pad. Washing the polished silicon wafer takes a considerable time, which hinders an improvement in the productivity and cost reduction.

To cope with the above, the present invention provides a rinsing composition for a silicon wafer that can shorten a washing time of a polished silicon wafer and reduce the LPD, a method for rinsing a silicon wafer using the same, and a method for producing a silicon wafer and a method for producing a semiconductor substrate using the same.

### Means for Solving Problem

A rinsing composition for a silicon wafer of the present invention is a rinsing composition for a silicon wafer, including a water-soluble polymer and an aqueous medium. The water-soluble polymer exhibits a difference (Z−Z₀) between a zeta-potential Z of a water-soluble polymer-containing silica aqueous dispersion (aqueous dispersion S) and a zeta-potential Z₀ of a silica aqueous dispersion (aqueous dispersion S₀) of 25 mV or less. The aqueous dispersion S consists of the water-soluble polymer, silica particles, water, and as needed, hydrochloric acid or ammonia, and has a concentration of the water-soluble polymer of 0.1 mass %, a concentration of the silica particles of 0.1 mass %, and a pH of 7.0 at 25° C. The aqueous dispersion S₀ consists of silica particles, water, and as needed, hydrochloric acid or ammonia, and has a concentration of the silica particles of 0.1 mass %, and a pH of 7.0 at 25° C.

The rinsing composition for a silicon wafer of the present invention is a rinsing composition for a silicon wafer, containing a water-soluble polymer and an aqueous medium. The water-soluble polymer contains at least one selected from the group consisting of polyglycerin, polyglycerin derivative, polyglycidol, polyglycidol derivative, polyvinyl alcohol derivative, and polyacrylamide.

A method for rinsing a silicon wafer of the present invention includes a step of rinsing a polished silicon wafer using the rinsing composition for a silicon wafer of the present invention.

A method for producing a silicon wafer of the present invention includes:

a polishing step of polishing a silicon wafer to be polished using a polishing liquid composition that contains silica particles, a water-soluble polymer B (where the water-soluble polymer contained in the rinsing composition for a silicon wafer of the present invention is referred to as a water-soluble polymer A), a nitrogen-containing basic compound, and an aqueous medium;

a rinsing step of rinsing the polished silicon wafer using the rinsing composition of the present invention; and

a washing step of washing the rinsed silicon wafer.

The water-soluble polymer A and the water-soluble polymer B may be the same or different from each other.

A method for producing a semiconductor substrate of the present invention includes a step of rinsing a polished silicon wafer using the rinsing composition for a silicon wafer of the present invention.

The method for producing a semiconductor substrate of the present invention includes a step of producing a silicon wafer by the method for producing a silicon wafer of the present invention.

### Effects of the Invention

The present invention relates to a rinsing composition for a silicon wafer that can shorten a washing time of a polished silicon wafer and reduce surface defects (LPD), a method for rinsing a silicon wafer using the same, and a method for producing a silicon wafer and a method for producing a semiconductor substrate using the same.

### DESCRIPTION OF THE INVENTION

The present invention is based on the finding that a rinsing composition for a silicon wafer (hereinafter, also referred to as a “rinsing composition” simply) containing a specific water-soluble polymer can shorten a washing time of a polished silicon wafer and reduce the surface defects (LPD). The specific water-soluble polymer is a water-soluble polymer (hereinafter also called a “water-soluble polymer A”) that has a property of exhibiting a difference (Z−Z₀) between a zeta-potential Z of a water-soluble polymer-containing silica aqueous dispersion (aqueous dispersion S) and a zeta-potential Z₀ of a silica aqueous dispersion (aqueous dispersion S₀) of 25 mV or less. Here, the aqueous dispersion S consists of the water-soluble polymer, silica particles, water, and as needed, hydrochloric acid or ammonia, and has a concentration of the water-soluble polymer of 0.1 mass %, a concentration of the silica particles of 0.1 mass %, and a pH of 7.0 at 25° C. The aqueous dispersion S₀ consists of silica particles, water, and as needed, hydrochloric acid or ammonia, and has a concentration of the silica particles of 0.1 mass %, and a pH of 7.0 at 25° C.

The mechanism of developing the effect of the present invention, that is, reducing the LPD of the polished silicon wafer and shortening the washing time when the rinsing composition of the present invention is used for a rinsing treatment of the polished silicon wafer, is assumed as below.

When the rinsing treatment using the rinsing composition of the present invention starts by supplying the rinsing composition, a water-soluble polymer B (a constituent of a polishing liquid composition) that has been absorbing on the surfaces of the silicon wafer and silica particles after polishing is replaced with the water-soluble polymer A by physical forces created by relative movement of a pad with respect to the polished silicon wafer. This replacement prevents the silica particles from reattaching on the surfaces of the polished silicon wafer, thereby significantly reducing the amount of the silica particles remaining on the polished silicon wafer to be washed, and reducing the aggregation of the silica particles because, even when the water-soluble polymer A adsorbs on the silica particles, it does not largely fluctuate the zeta-potential of the silica particles and can keep the zeta-potential of the silica particles at a large negative value. Therefore, the rinsing composition of the present invention containing the water-soluble polymer A can reduce the LPD of the polished silicon wafer and shorten the washing time.

[Rinsing Composition]

The rinsing composition of the present invention contains the water-soluble polymer A, an aqueous medium, and an optional component within a range that does not impair the effect of the present invention. The details of the optional component will be described later.

[Water-Soluble Polymer A]

The water-soluble polymer A is a water-soluble polymer that has a property of exhibiting the difference (Z−Z₀) between the zeta-potential Z of the aqueous dispersion S and the zeta-potential Z₀ of the aqueous dispersion S₀ of 25 mV or less. Here, the aqueous dispersion S is a water-soluble polymer-containing silica aqueous dispersion that consists of the water-soluble polymer A, silica particles, water, and as needed, hydrochloric acid or ammonia, and that has a concentration of the water-soluble polymer A of 0.1 mass %, a concentration of the silica particles of 0.1 mass %, and a pH of 7.0 at 25° C. The aqueous dispersion S₀ is a silica aqueous dispersion that consists of silica particles, water, and as needed, hydrochloric acid or ammonia, and that has a concentration of the silica particles of 0.1 mass %, and a pH of 7.0 at 25° C. The zeta-potential can be measured by the method described in Examples. When the water-soluble polymer A is composed of two or more kinds of water-soluble polymers, a mixture of the two or more kinds of water-soluble polymers has the property of exhibiting the difference (Z−Z₀) of 25 mV or less. When the water-soluble polymer A is a mixture of the two or more kinds of water-soluble polymers, the “concentration of the water-soluble polymer A of 0.1 mass %” means that the concentration of the mixture in the aqueous dispersion S is 0.1 mass %, i.e., the total concentration of the water-soluble polymers in the aqueous dispersion S is 0.1 mass %.

When the water-soluble polymer A is composed only of a water-soluble polymer a1 described below, the difference (Z−Z₀) is 25 mV or less, preferably 15 mV or less, more preferably 9 mV or less, and further preferably 7 mV or less, from the viewpoint of preventing the aggregation of silica particles.

When the water-soluble polymer A is a mixture of the water-soluble polymer a1 and a water-soluble polymer a2 described below, the difference (Z−Z₀) is 25 mV or less, preferably 15 mV or less, more preferably 12 mV or less, and further preferably 9 mV or less, from the viewpoint of preventing the aggregation of silica particles.

The zeta-potential Z₀ of the aqueous dispersion S₀ is a predetermined value within a range from, e.g., −40 mV to −50 mV, and may be a zeta-potential (e.g., −46 mV) of the aqueous dispersion S₀ that has been adjusted using a silica stock solution (“PL-3” manufactured by FUSO CHEMICAL CO., LTD.).

When the water-soluble polymer A is composed only of the water-soluble polymer a1 described below, the water-soluble polymer Ahas a ratio (d/d₀) of a secondary particle diameter d of the silica particles in the aqueous dispersion S to a secondary particle diameter d₀ of the silica particles in the aqueous dispersion S₀ of preferably 1.35 or less, more preferably 1.17 or less, further preferably 1.10 or less, and still further preferably 1.08 or less from the viewpoint of preventing the aggregation of silica particles, while the ratio (d/d₀) is preferably 1.00 or more, more preferably 1.02 or more, further preferably 1.04 or more, and still further preferably 1.05 or more from the viewpoint of reducing the LPD.

When the water-soluble polymer A is the mixture of the water-soluble polymer a1 and water-soluble polymer a2 described below, the water-soluble polymer A has a ratio (d/d₀) of the secondary particle diameter d of the silica particles in the aqueous dispersion S to the secondary particle diameter d₀ of the silica particles in the aqueous dispersion S₀ of preferably 1.35 or less, more preferably 1.34 or less, further preferably 1.33 or less, and still further preferably 1.32 or less from the viewpoint of preventing the aggregation of silica particles, while the ratio (d/d₀) is preferably 1.00 or more, more preferably 1.25 or more, further preferably 1.30 or more, and still further preferably 1.31 or more from the viewpoint of reducing the LPD.

The secondary particle diameter d₀ of the silica particles in the aqueous dispersion S₀ is a predetermined value within a range from, e.g., 64 to 73 nm, preferably a predetermined value within a range from 66 to 69 nm, and it may be a secondary particle diameter (e.g., 68.4 nm) of the silica particles in the aqueous dispersion S₀ containing a silica stock solution (“PL-3” manufactured by FUSO CHEMICAL CO., LTD) as a supply source of silica particles.

The content of the water-soluble polymer A in the rinsing composition is preferably 0.001 mass % or more, more preferably 0.015 mass % or more, further preferably 0.020 mass % or more, still further preferably 0.025 mass % or more, and yet further preferably 0.03 mass % or more from the viewpoint of shortening the washing time and reducing the LPD, while the content thereof is preferably 1.0 mass % or less, more preferably 0.7 mass % or less, further preferably 0.4 mass % or less, still further preferably 0.1 mass % or less, and yet further preferably 0.08 mass % or less from the same viewpoint.

The water-soluble polymer A is preferably at least one water-soluble polymer a1 selected from the group consisting of polyglycerin, polyglycerin derivative, polyglycidol, polyglycidol derivative, polyvinyl alcohol derivative, and polyacrylamide, from the viewpoint of shortening the washing time and reducing the LPD.

The polyglycerin derivative is preferably a polyglycerin derivative obtained by adding a functional group to polyglycerin via ether linkage or ester linkage, and more preferably a polyglycerin derivative obtained by adding a functional group to polyglycerin via ether linkage.

The polyglycerin derivative is preferably polyglycerin alkyl ether, polyglycerin dialkyl ether, polyglycerin fatty acid ester, polyethylene oxide-added polyglycerin, polypropylene oxide-added polyglycerin, aminated polyglycerin, etc., and more preferably polyglycerin alkyl ether, from the viewpoint of shortening the washing time and reducing the LPD. These may be used alone or in combination of two or more kinds.

The polyglycidol derivative is preferably polyglycidol alkyl ether, polyglycidol dialkyl ether, polyglycidol fatty acid ester, polyethylene oxide-added polyglycidol, polypropylene oxide-added polyglycidol, aminated polyglycidol, etc., from the viewpoint of shortening the washing time and reducing the LPD. These may be used alone or in combination of two or more kinds.

The polyvinyl alcohol derivative is preferably polyethylene oxide-modified polyvinyl alcohol, sulfonic acid-modified polyvinyl alcohol, etc., from the viewpoint of shortening the washing time and reducing the LPD. These may be used alone or in combination of two or more kinds.

Among the above, the water-soluble polymer a1 is more preferably at least one selected from the group consisting of polyglycerin, polyglycerin alkyl ether, polyglycerin dialkyl ether, polyglycerin fatty acid ester, polyethylene oxide-modified polyvinyl alcohol, sulfonic acid-modified polyvinyl alcohol, and polyacrylamide, further preferably at least one selected from the group consisting of polyglycerin and polyglycerin alkyl ether, and still further preferably polyglycerin alkyl ether, from the viewpoint of shortening the washing time and reducing the LPD. The water-soluble polymer a1 may be two or more kinds of the above. The rinsing composition preferably contains both of polyglycerin and polyglycerin alkyl ether from the viewpoint of shortening the washing time and reducing the LPD. The number of carbon atoms of the hydrophobic group of the polyglycerin derivative is preferably 6 or more, and more preferably 8 or more, and preferably 22 or less, and more preferably 18 or less.

When the water-soluble polymer a1 contains both of polyglycerin and polyglycerin alkyl ether, the mass ratio (polyglycerin/polyglycerin alkyl ether) is preferably 0.5 or more, more preferably 1.0 or more, and further preferably 2.0 or more from the viewpoint of reducing the LPD, while the mass ratio is preferably 10 or less, more preferably 6.0 or less, and further preferably 5.0 or less from the same viewpoint.

The weight average molecular weight of the water-soluble polymer a1 is preferably 500 or more, more preferably 700 or more, and further preferably 900 or more from the viewpoint of shortening the washing time and reducing the LPD, while the weight average molecular weight thereof is preferably 1,500,000 or less, more preferably 500,000 or less, further preferably 100,000 or less, still further preferably 25,000 or less, and yet further preferably 10,000 or less from the same viewpoint. The weight average molecular weight of the water-soluble polymer A can be measured by the method described in Examples.

The water-soluble polymer a1 is made up of preferably 5 or more monomer units, more preferably 10 or more monomer units, and further preferably 15 or more monomer units from the viewpoint of shortening the washing time and reducing the LPD, while the water-soluble polymer a1 is made up of preferably 5,000 or less monomer units, more preferably 500 or less monomer units, further preferably 200 or less monomer units, still further preferably 150 or less monomer units, and yet further preferably 100 or less monomer units from the same viewpoint.

The water-soluble polymer A is preferably a mixture of the water-soluble polymer a1 and a water-soluble polymer having a betaine structure (hereinafter, the “water-soluble polymer having a betaine structure” is also referred to as a “water-soluble polymer a2” simply) from the viewpoint of reducing the LPD.

[Water-Soluble Polymer Having a Betaine Structure]

In the present application, the betaine structure is a structure in which positive electric charge and negative electric charge are present in the same molecule, and electric charge is neutralized. The betaine structure has the positive electric charge and negative electric charge preferably at a position not adjacent to each other, and preferably at a position with one or more atoms interposed therebetween.

The water-soluble polymer a2 is preferably at least one water-soluble polymer selected from a homopolymer of a monomer having a betaine structure, a copolymer of a monomer having a betaine structure and a monomer having a hydrophobic group, a copolymer of a monomer having a betaine structure and a monomer having a hydroxyl group, a copolymer of a monomer having a betaine structure and a monomer having an oxyalkylene group, a copolymer of a monomer having a betaine structure and a monomer having an amino group, and a copolymer of a monomer having a betaine structure and a monomer having a quaternary ammonium group, and more preferably a copolymer of a monomer having a betaine structure and a monomer having a hydrophobic group, from the viewpoint of reducing the LPD.

Examples of the betaine structure include sulfobetaine, carbobetaine, and phosphobetaine. Among these, carbobetaine and phosphobetaine are more preferred, and phosphobetaine is further preferred, from the viewpoint of reducing the LPD.

A constitutional unit A derived from the monomer having a betaine structure is preferably a constitutional unit expressed by Formula (1) below, from the viewpoint of reducing the LPD.

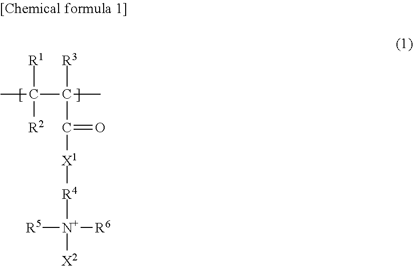

In Formula (1) above,

R¹ to R³ are the same or different and represent a hydrogen atom, a methyl group or an ethyl group,

R⁴ is an alkylene group with 1 to 4 carbon atoms or —Y¹—OPO₃⁻—Y²—,

Y¹ and Y² are the same or different and represent an alkylene group with 1 to 4 carbon atoms,

R⁵ and R⁶ are the same or different and represent a hydrocarbon group with 1 to 4 carbon atoms,

X¹ is O or NR⁷,

R⁷ is a hydrogen atom or a hydrocarbon group with 1 to 4 carbon atoms,

X² is a hydrocarbon group with 1 to 4 carbon atoms, —R¹⁷SO₃⁻ or —R⁸COO⁻, and

R¹⁷ and R¹⁸ are the same or different and represent an alkylene group with 1 to 4 carbon atoms.

When R⁴ is an alkylene group with 1 to 4 carbon atom, X² is —R¹⁷SO₃⁻ or —R¹⁸COO⁻. When R⁴ is —Y¹—OPO₃⁻—Y²—, X² is a hydrocarbon group with 1 to 4 carbon atoms.

R¹ and R² are both preferably a hydrogen atom, from the viewpoint of availability of monomer, polymerization property of monomer, and reduction of the LPD.

R³ is preferably a hydrogen atom or a methyl group, and more preferably a methyl group, from the viewpoint of availability of monomer, polymerization property of monomer, and reduction of the LPD.

X¹ is preferably O (oxygen atom), from the viewpoint of availability of monomer, polymerization property of monomer, and reduction of the LPD.

R⁴ is preferably an alkylene group with 2 or 3 carbon atoms or —Y¹—OPO₃⁻—Y²—, more preferably an alkylene group with 2 carbon atoms or —Y¹—OPO₃⁻—Y²—, and further preferably —Y¹—OPO₃⁻—Y²—, from the viewpoint of reducing the LPD.

Y¹ and Y² are both preferably an alkylene group with 2 or 3 carbon atoms, and more preferably an alkylene group with 2 carbon atoms, from the viewpoint of availability of monomer, polymerization property of monomer, and reduction of the LPD.

R⁵ and R⁶ are both preferably a methyl group or an ethyl group, and more preferably a methyl group, from the viewpoint of availability of monomer, polymerization property of monomer, and reduction of the LPD.

When R⁴ is an alkylenes group with 1 to 4 carbon atoms, X² is —R¹⁷SO₃⁻ or —R¹⁸COO⁻, and from the viewpoint of reducing the LPD, X² is preferably —R¹⁸COO⁻. When R⁴ is —Y¹—OPO₃⁻—Y²—, X² is a hydrocarbon group with 1 to 4 carbon atoms, and from the viewpoint of reducing the LPD, X² is more preferably a methyl group.

The number of carbon atoms of R¹⁷ is preferably 1 to 3, and more preferably 2 to 3, from the viewpoint of availability of monomer, polymerization property of monomer, and reduction of the LPD. The number of carbon atoms of R¹⁸ is preferably 1 to 3, and more preferably 1 to 2, from the viewpoint of availability of unsaturated monomer, polymerization property of monomer, and reduction of the LPD.

The constitutional unit A is preferably a constitutional unit derived from at least one monomer selected from sulfobetaine methacrylate, methacryloyloxyethyl phosphorylcholine, and carboxybetaine methacrylate, more preferably a constitutional unit derived from at least one monomer selected from methacryloyloxyethyl phosphorylcholine and carboxybetaine methacrylate, and further preferably a constitutional unit derived from methacryloyloxyethyl phosphorylcholine, from the viewpoint of reducing the LPD.

When the water-soluble polymer a2 is a copolymer of a monomer having a betaine structure and at least one monomer selected from a monomer having a hydrophobic group, a monomer having a hydroxyl group, a monomer having an oxyalkylene group, a monomer having an amino group and a monomer having a quaternary ammonium group (hereinafter, also referred to as a “monomer B” simply), for example, a constitutional unit B derived from the monomer B is preferably a constitutional unit B expressed by Formula (2) below, from the viewpoint of reducing the LPD.

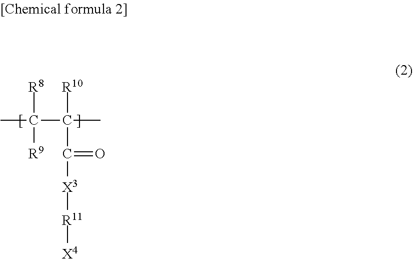

In Formula (2) above,

R⁸ to R¹⁰ are the same or different and represent a hydrogen atom, a methyl group or an ethyl group,

X³ is O or NR¹⁹,

R¹⁹ is a hydrogen atom or a hydrocarbon group with 1 to 4 carbon atoms,

R¹¹ is an alkylene group with 1 to 22 carbon atoms (the hydrogen atom of the alkylene group may be substituted with a hydroxyl group) or -(AO)ₘ— (where AO represents an alkyleneoxy group with 2 to 4 carbon atoms, and m represents an average number of added moles of 1 to 150),

X⁴ is a hydrogen atom, a hydrocarbon group with 1 to 4 carbon atoms (the hydrogen atom of the hydrocarbon group may be substituted with a hydroxyl group), a hydroxyl group, N⁺R¹²R¹³R¹⁴ or NR¹⁵R¹⁶, and

R¹² to R¹⁶ are the same or different and represent a hydrogen atom or a hydrocarbon group with 1 to 4 carbon atoms.

R⁸ and R⁹ are both preferably a hydrogen atom, from the viewpoint of availability of monomer, polymerization property of monomer, and reduction of the LPD.

R¹⁰ is preferably a hydrogen atom or a methyl group, and more preferably a methyl group, from the viewpoint of availability of monomer, polymerization property of monomer, and reduction of the LPD.

X³ is preferably 0, from the viewpoint of availability of monomer, polymerization property of monomer, and reduction of the LPD.

When X⁴ is a hydrogen atom, the number of carbon atoms of the alkylene group of R¹¹ is preferably 3 or more, more preferably 4 or more, and further preferably 6 or more, and preferably 18 or less, and more preferably 12 or less, from the viewpoint of availability of monomer, polymerization property of monomer, and reduction of the LPD, and m is preferably 2 to 30 from the same viewpoint.

When X⁴ is a hydrocarbon group with 1 to 4 carbon atoms, R¹¹ is preferably -(AO)ₘ—, and the m is preferably 4 to 90, from the viewpoint of availability of monomer, polymerization property of monomer, and reduction of the LPD.

AO is preferably composed of at least one alkyleneoxy group selected from an ethyleneoxy group (EO) (an alkyleneoxy group with 2 carbon atoms) and a propyleneoaxy group (PO) (an alkyleneoxy group with 3 carbon atoms), and more preferably composed of EO, from the viewpoint of availability of monomer, polymerization property of monomer, and reduction of the LPD. When -(AO)ₘ-contains two more kinds of alkyleneoxy groups having different number of carbon atoms, the sequences of the alkyleneoxy groups may be a block type or a random type, and preferably a block type.

When X⁴ is a hydroxyl group, N⁺R¹²R¹³R¹⁴ or NR¹⁵R¹⁶, R¹¹ is preferably an alkylene group with 1 to 22 carbon atoms (the hydrogen atom of the hydrocarbon group may be substituted with a hydroxyl group) from the viewpoint of availability of monomer, polymerization property of monomer, and reduction of the LPD, and the number of carbon atoms of the alkylene group is preferably 2 or more, preferably 3 or less, and more preferably 2 from the same viewpoint.

X⁴ is preferably a hydrogen atom, a methyl group, a hydroxyl group or N⁺R¹²R¹³R¹⁴ from the viewpoint of availability of monomer, polymerization property of monomer, and reduction of the LPD, and R¹² to R¹⁴ are all preferably a methyl group or an ethyl group, and more preferably a methyl group from the same viewpoint.

The constitutional unit B is preferably a constitutional unit derived from at least one monomer selected from an unsaturated monomer having a hydrophobic group (the hydrogen atom of the hydrophobic group may be substituted with a hydroxyl group) such as alkyl methacrylate, an unsaturated monomer having a cationic group such as methacrylate having a quaternary ammonium cation, and an unsaturated monomer having a nonionic group such as methacrylate having an ethyleneoxy group, and more preferably a constitutional unit derived from an unsaturated monomer having a hydrophobic group (the hydrogen atom of the hydrophobic group may be substituted with a hydroxyl group) such as alkyl methacrylate, from the viewpoint of availability of monomer, polymerization property of monomer, and reduction of the LPD.

The constitutional unit B is more preferably a constitutional unit derived from at least one monomer selected from butylmethacrylate (BMA), 2-ethylhexyl methacrylate (EHMA), lauryl methacrylate (LMA), stearyl methacrylate (SMA), methacryloylwxyethyldimethyl ethylaminium (MOEDES), trimethyl[2-hydroxy-3-(methacryloylaxy)propyl]aminium (THMPA), methacryloylethyl trimethylaminium (MOETMA), methoxypolyethylene glycol methacrylate (MPEGMA), polyethylene glycol methacrylate (PEGMA), methoxypolypropylene glycol methacrylate (MPPGMA), polypropylene glycol methacrylate (PPGMA), and hydroxyethyl methacrylate (HEMA), and more preferably a constitutional unit derived from at least one monomer selected from BMA and LMA.

(Mole Ratio of the Constitutional Unit a to the Constitutional Unit B)

The mole ratio of the constitutional unit A to the constitutional unit B (the constitutional unit A/the constitutional unit B) in the water-soluble polymer a2 is preferably 10/90 or more, more preferably 20/80 or more, and further preferably 30/70 or more from the viewpoint of reducing the LPD, while the mole ratio is preferably 98/2 or less, and more preferably 95/5 or less from the same viewpoint

(Constitutional Unit Other than the Constitutional Unit A and the Constitutional Unit B)

The water-soluble polymer a2 may contain a constitutional unit other than the constitutional unit A and the constitutional unit B within a range that does not impair the effect of the present invention. The constitutional unit other than the constitutional unit A and the constitutional unit B is preferably a constitutional unit derived from a hydrophobic unsaturated monomer such as styrene.

The content of the constitutional unit other than the constitutional unit A and the constitutional unit B in the water-soluble polymer a2 is preferably 1 mass % or less, more preferably 0.5 mass % or less, further preferably 0.1 mass % or less, and still further preferably 0.05 mass % or less. The content of the constitutional unit other than the constitutional unit A and the constitutional unit B in the water-soluble polymer a2 may be 0 mass %.

The total content of the constitutional unit A and the constitutional unit B in the water-soluble polymer a2 is preferably 99 mass % or more, more preferably 99.5 mass % or more, further preferably 99.9 mass % or more, and yet further preferably 99.95 mass % or more, and it may be 100 mass %.

The weight average molecular weight of the water-soluble polymer a2 is preferably 1,000 or more, more preferably 3,000 or more, further preferably 5,000 or more from the viewpoint of reducing the LPD, while the weight average molecular weight thereof is preferably 1,500,000 or less, more preferably 1,200,000 or less, and further preferably 1,000,000 or less from the viewpoint of improving the solubility of the water-soluble polymer a2 and reducing the LPD.

The content of the water-soluble polymer a2 in the rinsing composition of the present invention is preferably 0.00001 mass % or more, more preferably 0.00005 mass % or more, and further preferably 0.0001 mass % or more from the viewpoint of reducing the LPD, while the content thereof is preferably 10 mass % or less, more preferably 5 mass % or less, and further preferably 1 mass % or less from the viewpoint of reducing the LPD.

A mass ratio of the water-soluble polymer a1 to the water-soluble polymer a2 (the water-soluble polymer a1/the water-soluble polymer a2) in the rinsing composition of the present invention is preferably 0.5 or more, more preferably 1 or more, and further preferably 2 or more from the viewpoint of reducing the LPD, while the mass ratio is preferably 500 or less, more preferably 200 or less, and further preferably 100 or less from the viewpoint of reducing the LPD.

[Aqueous Medium]

The aqueous medium contained in the rinsing composition of the present invention may be water such as ion exchanged water or ultrapure water, or a mixed medium of water and a solvent. The solvent is, e.g., polyhydric alcohol with 2 to 4 carbon atoms, and preferably glycerin or propylene glycol. The water in the aqueous medium is preferably ion exchanged water or ultrapure water, and more preferably ultrapure water. When the aqueous medium is a mixed medium of water and a solvent, the proportion of water with respect to the whole mixed medium is preferably 90 mass % or more, more preferably 92 mass % or more, and further preferably 95 mass % or more, from the viewpoint of cost effectiveness.

The content of the aqueous medium in the rinsing composition of the present invention is preferably a remainder after subtracting the water-soluble polymer A, and a basic compound described below and an optional component described below, which are added as needed, from the total amount of the rinsing composition.

[Optional Component (Aid)]

The rinsing composition of the present invention may further contain at least one optional component selected from a pH regulator, an antiseptic agent, alcohol, a chelating agent, an anionic surfactant, and a nonionic surfactant within a range that does not impair the effect of the present invention.

[pH Regulator]

Examples of the pH regulator include a basic compound, an acidic compound, and salts thereof. The salt of the acidic compound is preferably at least one selected from alkali metal salt, ammonium salt, and amine salt, and more preferably ammonium salt. The counter ion when the basic compound takes the form of salt is preferably at least one selected from hydroxide ion, chloride ion, and iodide ion, and more preferably at least one selected from hydroxide ion and chloride ion.

(Basic Compound)

Examples of the basic compound include sodium hydroxide, potassium hydroxide, ammonia, ammonium hydroxide, ammonium carbonate, ammonium hydrogencarbonate, methylamine, dimethylamine, trimethylamine, ethylamine, diethylamine, triethylamine, monoethanolamine, diethanolamine, triethanolamine, N-methylethanolamine, N-methyl-N,N-diethanolamine, N,N-dimethylethanolamine, N,N-diethylethanolamine, N,N-dibutylethanolamine, N-(β-aminoethyl)ethanolamine, monoisopropanolamine, diisopropanolamine, triisopropanolamine, ethylenediamine, hexamethylenediamine, piperazine hexahydrate, anhydrous piperazine, 1-(2-aminoethyl)piperazine, N-methylpiperazine, diethylenetriamine, tetramethylammonium hydroxide, tetraethylammonium hydroxide, tetrapropylammonium hydroxide, and tetrabutylammonium hydroxide. The basic compound may be a combination of two or more kinds of these. The basic compound is more preferably ammonia from the viewpoint of reducing the haze of a silicon wafer while reducing the LPD, and improving the storage stability of the rinsing composition.

(Acidic Compound)

Examples of the acidic compound include: inorganic acids such as sulfuric acid, hydrochloric acid, nitric acid, and phosphoric acid; and organic acids such as acetic acid, oxalic acid, succinic acid, glycolic acid, malic acid, citric acid, and benzoic acid.

[Antiseptic Agent]

Examples of the antiseptic agent include phenoxyethanol, benzalkonium chloride, benzethonium chloride, 1,2-benzisothiazolin-3-one, (5-chloro-)2-methyl-4-isothiazoline-3-one, hydrogen peroxide, and hypochlorite.

[Alcohol]

Examples of the alcohol include methanol, ethanol, propanol, butanol, isopropyl alcohol, 2-methyl-2-propanol, ethylene glycol, propylene glycol, polyethylene glycol, and glycerin. The content of the alcohol in the rinsing composition of the present invention is preferably 0.01 mass % to 10 mass %.

[Chelating Agent]

Examples of the chelating agent include 1-hydroxyethane 1,1-diphosphonic acid, ethylenediamine tetraacetic acid, sodium ethylenediamine tetraacetate, nitrilotriacetic acid, sodium nitrilotriacetate, ammonium nitrilotriacetate, hydroxyethylethylenediamine triacetic acid, sodium hydroxyethylethylenediamine triacetate, triethylenetetramine hexaacetic acid, and sodium triethylenetetramine hexaacetate. The content of the chelating agent in the rinsing composition of the present invention is preferably 0.001 to 10 mass %.

[Anionic Surfactant]

Examples of the anionic surfactant include: carboxylates such as fatty acid soap and alkyl ether carboxylate; sulfonates such as alkyl benzene sulfonate and alkyl naphthalene sulfonate; sulfates such as fatty alcohol sulfate and alkyl ether sulfate; and phosphates such as alkyl phosphate.

[Nonionic Surfactant]

Examples of the nonionic surfactant include: polyethylene glycol types such as polyoxyethylene sorbitan fatty acid ester, polyoxyethylene sorbitol fatty acid ester, polyoxyethylene glycerine fatty acid ester, polyoxyethylene fatty acid ester, polyoxyethylene alkyl ether, polyoxyethylene alkyl phenyl ether, and polyoxyalkylene (hydrogenated) castor oil; polyhydric alcohol types such as sucrose fatty acid ester and alkyl glycoside; and fatty acid alkanolamide.

The pH at 25° C. of the rinsing composition of the present invention is preferably 2 or more, more preferably 2.5 or more, and further preferably 3.0 or more from the viewpoint of shortening the washing time, reducing the LPD, and improving the storage stability of the rinsing composition, while the pH thereof is preferably 12 or less, more preferably 11.5 or less, and further preferably 11.0 or less from the same viewpoint. The pH can be adjusted by adding a pH regulator appropriately as needed. The pH at 25° C. can be measured using a pH meter (“HM-30G” manufactured by DKK-TOA CORPORATION) and is a value read on the pH meter one minute after dipping an electrode into the rinsing composition.

The content of each component described above is the content of each component in use. The rinsing composition of the present invention may be preserved and provided in the form of a concentrate as long as its storage stability is not impaired. This is preferred because the production and transportation costs can be reduced further. The concentrate may be diluted appropriately with the above aqueous medium as needed for use. The concentration rate is not particularly limited as long as the concentration after dilution is suitable for polishing, but preferably 2 times or more, more preferably 10 times or more, further preferably 20 times or more, and still further preferably 30 times or more, from the viewpoint of reducing the production and transportation costs further.

When the rinsing composition of the present invention is the concentrate, the content of the water-soluble polymer A in the concentrate is preferably 0.02 mass % or more, more preferably 0.1 mass % or more, further preferably 0.5 mass % or more, still further preferably 1.0 mass % or more, and yet further preferably 1.5 mass % or more from the viewpoint of reducing the production and transportation costs, while the content thereof is preferably 20 mass % or less, more preferably 15 mass % or less, further preferably 10 mass % or less, and still further preferably 7.0 mass % or less from the viewpoint of improving the storage stability.

When the rinsing composition of the present invention is the concentrate, the pH of the concentrate at 25° C. is preferably 1.5 or more, more preferably 1.7 or more, and further preferably 2.0 or more, and preferably 12.5 or less, more preferably 12.0 or less, and further preferably 11.5 or less.

[Production Method of Rinsing Composition]

The rinsing composition of the present invention can be produced, for example, by a production method that includes a step of blending the water-soluble polymer A, the aqueous medium, and as needed the optional component by a known method. In the present disclosure, the “blending” includes mixing the water-soluble polymer A and as needed the optional component with the aqueous medium simultaneously or sequentially. The order of mixing the components is not particularly limited.

The blending can be carried out using a mixer such as a homomixer, a homogenizer, an ultrasonic disperser, or a wet ball mill. The blending amount of each component in the production method of the rinsing composition of this embodiment can be the same as the content of each component in the rinsing composition described above.

[Production Method of Semiconductor Substrate]

The rinsing composition of the present invention is used to remove residues remaining on the surfaces of a silicon wafer that has been polished using a polishing liquid composition containing abrasive grains and a water-soluble polymer B. An exemplary production method of a semiconductor substrate of the present invention includes: a polishing step of polishing a silicon wafer to be polished (hereinafter, also referred to as a “substrate to be polished”) using a polishing liquid composition containing abrasive grains; a rinsing step of subjecting the polished silicon wafer to a rinsing treatment using the rinsing composition of the present invention; and a washing step of washing the silicon wafer that has been rinsed in the rinsing step (hereinafter, also referred to as a “rinsed silicon wafer”). An exemplary semiconductor substrate is a silicon wafer, and an exemplary production method of a semiconductor substrate of the present invention is a production method of a silicon wafer. Another exemplary production method of a semiconductor substrate of the present invention is a production method of a semiconductor substrate including a step of producing a silicon wafer by the production method of a silicon wafer of the present invention, the step including a polishing step of polishing a silicon wafer to be polished using a polishing liquid composition; a rinsing step of rinsing the polished silicon wafer using the rinsing composition of the present invention; and a washing step of washing the rinsed silicon wafer.

The polishing step includes a lapping (rough polishing) step, an etching step and a final polishing step. The lapping step includes planarizing a silicon wafer that has been obtained by slicing a silicon single crystal ingot into thin disks. The etching step includes etching the lapped silicon wafer, and the final polishing step includes mirror-finishing the surfaces of the silicon wafer.

In the polishing step, for example, the polishing liquid composition is supplied between a silicon wafer to be polished and a pad, and then the pad is moved relative to the silicon wafer while the silicon wafer is in contact with the pad. The polishing conditions such as the number of revolutions of the pad, the number of revolutions of the substrate to be polished, the polishing load of a polishing machine equipped with the pad, the supply rate of the polishing liquid composition, and polishing time can be the same as those known conventionally.

It is preferred that the polishing composition used in the polishing step contains, e.g., silica particles as the abrasive grains and the water-soluble polymer B from the viewpoint of improving the polishing rate and reducing the surface roughness (haze) of a silicon wafer.

In the rinsing step, for example, the rinsing composition is supplied between a polished silicon wafer and a pad, and then the pad is moved relative to the polished silicon wafer while the silicon wafer is in contact with the pad. The rinsing treatment in the rinsing step can be carried out using the polishing machine used in the polishing step. The conditions such as the number of revolutions of the pad, the number of revolutions of the polished silicon wafer, the load of the polishing machine equipped with the pad, and the supply rate of the rinsing composition may be the same as or different from the corresponding conditions in the polishing step. The rinsing time is preferably 1 second or more, and more preferably 3 seconds or more from the viewpoint of preventing the attachment of abrasive grains, while the rinsing time is preferably 60 seconds or less, and more preferably 30 seconds or less from the viewpoint of improving the productivity. Here, the rinsing time refers to a time during which the rinsing composition is supplied.

The rinsing step may include a water rinsing treatment using water as a rinsing agent, prior to the rinsing treatment using the rinsing composition of the present invention. The water rinsing treatment time is preferably 2 seconds or more and 30 seconds or less.

The pad used in the rinsing step may be the same as that used in the polishing step, and may be any type such as a nonwoven fabric type or a suede type. The pad used in the polishing step may be used directly in the rinsing step without replacement. In this case, the pad may contain a certain amount of abrasive grains of the polishing liquid composition. The rinsing step can be carried out to the silicon wafer that is still attached to the polishing machine immediately after the polishing step.

The temperature of the rinsing composition used in the rinsing step is preferably 5 to 60° C.

It is appropriate that the rinsing step is carried out at least after the final polishing step, but it may be carried out after each of the rough polishing step and the final polishing step.

In the washing step, for example, the rinsed silicon wafer is soaked in a washing agent, or a washing agent is ejected onto the surface of the rinsed silicon wafer to be washed. Any conventionally known washing agent such as an aqueous solution containing ozone or an aqueous solution containing ammonium hydrogen fluoride may be used. The washing time may be set according to the washing method.

The polishing liquid composition used in the polishing step contains, e.g., silica particles, the water-soluble polymer B, a nitrogen-containing basic compound and an aqueous medium. The polishing composition preferably contains the water-soluble polymer B, from the viewpoint of improving the polishing rate while reducing the LPD.

[Water-Soluble Polymer B]

(1) Water-Soluble Polymer B

The water-soluble polymer B is a water-soluble polymer that exhibits the difference (z−z₀) between the zeta-potential z of the aqueous dispersion s and the zeta-potential to of the aqueous dispersion s₀ of 15 mV or more. Here, the aqueous dispersion s is a water-soluble polymer-containing silica aqueous dispersion that consists of the water-soluble polymer B, silica particles, water, and as needed, hydrochloric acid or ammonia, and that has a concentration of the water-soluble polymer B of 0.01 mass %, a concentration of the silica particles of 0.1 mass %, and a pH of 10.0 at 25° C. The aqueous dispersion s₀ is a silica aqueous dispersion that consists of silica particles, water, and as needed, hydrochloric acid or ammonia, and that has a concentration of the silica particles of 0.1 mass %, and a pH of 10.0 at 25° C. The zeta-potentials z and z₀ can be measured by the method described in Examples. When the water-soluble polymer B is composed of two or more kinds of water-soluble polymers, a mixture of the two or more kinds of water-soluble polymers B has the property of exhibiting the zeta-potential difference (z−z₀) of 15 mV or more.

The zeta-potential difference (z−z₀) is 15 mV or more, preferably 25 mV or more, and more preferably 30 mV or more from the viewpoint of improving the polishing rate, while the zeta-potential difference (z−z₀) is preferably 50 mV or less, and more preferably 46 mV or less from the viewpoint of reducing the LPD.

The zeta-potential z₀ of the aqueous dispersion s₀ is a predetermined value within a range from, e.g., −50 mV to −70 mV, and may be a zeta-potential (e.g., −61 mV) of the aqueous dispersion z₀ that has been adjusted using a silica stock solution (“PL-3” manufactured by FUSO CHEMICAL CO., LTD).

The water-soluble polymer B has a ratio (D/D₀) of a secondary particle diameter D of the silica particles in the aqueous dispersion s to a secondary particle diameter D₀ of the silica particles in the aqueous dispersion s₀ of preferably 1.10 or more, more preferably 1.15 or more, and further preferably 1.30 or more from the viewpoint of improving the polishing rate, while the ratio (D/D₀) is preferably 1.60 or less from the viewpoint of reducing the LPD.

The secondary particle diameter D₀ of the silica particles in the aqueous dispersion s₀ is a predetermined value within a range from, e.g., 64 to 73 nm, preferably a predetermined value within a range from 66 to 69 nm, and it may be a secondary particle diameter (e.g., 67.7 nm) of the silica particles in the aqueous dispersion s₀ containing a silica stock solution (“PL-3” manufactured by FUSO CHEMICAL CO., LTD) as a supply source of silica particles.

The water-soluble polymer B is preferably at least one selected from the group consisting of polysaccharide, alkyl acrylamide-based polymer, polyvinyl alcohol (PVA), and polyvinyl alcohol derivative (except for anion-modified polyvinyl alcohol). The polysaccharide is preferably hydroxyethyl cellulose (HEC). The alkyl acrylamide-based polymer is preferably poly(hydroxy)alkyl acrylamide and polyalkyl acrylamide, and more preferably polyhydroxyethyl acrylamide (pHEAA). The polyvinyl alcohol derivative is preferably a polyvinyl alcohol-polyethylene glycol-graft copolymer (PEG-g-PVA) and polyethylene oxide-modified polyvinyl alcohol Among these, the water-soluble polymer B is preferably at least one selected from the group consisting of HEC, poly(hydroxy)alkyl acrylamide, PVA, PEG-g-PVA, and polyethylene oxide-modified polyvinyl alcohol, more preferably at least one selected from the group consisting of HEC, pHEAA, and PVA, further preferably at least one selected from HEC and pHEAA, and still further preferably HEC, from the viewpoint of improving the polishing rate while reducing the LPD.

The weight average molecular weight of the water-soluble polymer B is preferably 10,000 or more, more preferably 50,000 or more, and further preferably 100,000 or more from the viewpoint of improving the polishing rate and reducing the LPD, while the weight average molecular weight thereof is preferably 5,000,000 or less, more preferably 3,000,000 or less, and further preferably 1,000,000 or less from the same viewpoint. The weight average molecular weight of the water-soluble polymer B can be measured by the method described in Examples.

The content of the water-soluble polymer B in the polishing liquid composition is preferably 0.001 mass % or more, more preferably 0.003 mass % or more, and further preferably 0.005 mass % or more from the viewpoint of improving the polishing rate, while the content thereof is preferably 1.0 mass % or less, more preferably 0.5 mass % or less, and further preferably 0.1 mass % or less from the same viewpoint.

When the water-soluble polymer A contained in the rinsing composition for use in the rinsing step is at least one selected from polyglycerin and polyglycerin derivative, the water-soluble polymer B contained in the polishing liquid composition for use in the polishing step is preferably HEC and poly(hydroxy)alkyl acrylamide, from the viewpoint of improving the polishing rate while reducing the LPD. When the water-soluble polymer A contained in the rinsing composition for use in the rinsing step is a polyglycerin derivative, the water-soluble polymer B contained in the polishing liquid composition for use in the polishing step is preferably HEC. In this case, the polyglycerin derivative preferably contains polyglycerin alkyl ether, and more preferably the polyglycerin derivative is polyglycerin alkyl ether.

[Silica Particles]

The silica particles contained in the polishing liquid composition is more preferably colloidal silica from the viewpoint of improving the surface smoothness of a silicon wafer, and preferably those obtained from a hydralysate of alkoxysilane from the viewpoint of preventing contamination of a silicon wafer with alkali metal, alkaline-earth metal, etc. The average primary particle diameter of the silica particles contained in the polishing liquid composition is preferably 5 nm or more, and more preferably 10 nm or more from the viewpoint of achieving a high polishing rate, while the average primary particle diameter thereof is preferably 50 nm or less, and more preferably 45 nm or less from the viewpoint of reducing the LPD. The average primary particle diameter of the silica particles can be calculated using a specific surface area S (m²/g) calculated by a BET (nitrogen adsorption) method.

The degree of association of the silica particles is preferably 1.1 or more and 3.0 or less, and more preferably 1.8 or more and 2.5 or less from the viewpoint of achieving a high polishing rate and reducing the LPD. The degree of association of the silica particles is a coefficient indicating the shape of the silica particles, and it is calculated by the formula below. The average secondary particle diameter is a value measured by a dynamic light scattering method, and it can be measured using a device described in Examples, for example.

Degree of association=average secondary particle diameter/average primary particle diameter

The content of the silica particles in the polishing liquid composition is preferably 0.05 mass % or more, and more preferably 0.1 mass % or more from the viewpoint of achieving a high polishing rate, while the content thereof is preferably 10 mass % or less, and more preferably 7.5 mass % or less from the viewpoint of cost effectiveness, preventing the aggregation of silica particles in the polishing liquid composition, and improving the dispersion stability.

[Nitrogen-Containing Basic Compound]

The nitrogen-containing basic compound contained in the polishing liquid composition is at least one selected from amine compound and ammonium compound from the viewpoint of achieving a high polishing rate and reducing the surface roughness (haze) and surface defects (LPD), and examples thereof include ammonia, ammonium hydroxide, ammonium carbonate, ammonium hydrogencarbonate, dimethylamine, trimethylamine, diethylamine, triethylamine, monoethanolamine, diethanolamine, triethanolamine, N-methylethanolamine, N-methyl-N,N-diethanolamine, N,N-dimethylethanolamine, N,N-diethylethanolamine, N,N-dibutylethanolamine, N-(3-aminoethyl)ethanolamine, monoisopropanolamine, diisopropanolamine, triisopropanolamine, ethylenediamine, hexamethylenediamine, piperazine hexahydrate, anhydrous piperazine, 1-(2-aminoethyl)piperazine, N-methylpiperazine, diethylenetriamine, tetramethyl ammonium hydroxide, and hydroxyamine. Among these, ammonia and a mixture of ammonia and hydroxyamine are preferred, and ammonia is more preferred.

The content of the nitrogen-containing basic compound in the polishing liquid composition is preferably 0.001 mass % or more, and more preferably 0.005 mass % or more from the viewpoint of reducing the surface roughness (haze) and surface defects (LPD) of a silicon wafer and achieving a high polishing rate, while the content thereof is preferably 1 mass % or less, and more preferably 0.5 mass % or less from the viewpoint of reducing the surface roughness (haze) and surface defects (LPD) of a silicon wafer.

[Aqueous Medium]

The aqueous medium contained in the polishing liquid composition may be the same as that contained in the rinsing composition of the present invention. The content of the aqueous medium in the polishing liquid composition may be a remainder after subtracting the silica particles, the water-soluble polymer B, the nitrogen-containing basic compound, and an optional component described below from the total amount of the polishing liquid composition.

The pH of the polishing liquid composition at 25° C. is preferably 8 or more, more preferably 9 or more, and further preferably 10 or more from the viewpoint of achieving a high polishing rate, while the pH thereof is preferably 12 or less, and more preferably 11 or less from the viewpoint of safety. The pH can be adjusted by appropriately adding the nitrogen-containing basic compound and/or a pH regulator. The pH at 25° C. can be measured using a pH meter (“HM-30G” manufactured by DKK-TOA CORPORATION) and is a value read on the pH meter one minute after dipping an electrode into the polishing liquid composition.

The polishing liquid composition can be produced, for example, by a production method that includes a step of blending the silica particles, the water-soluble polymer B, the aqueous medium, the nitrogen-containing basic compound, and as needed an optional component by a known method. The optional component may be at least one selected from a water-soluble polymer other than the water-soluble polymer B, a pH regulator, an antiseptic agent, alcohol, a chelating agent, and a nonionic surfactant.

The production method of a semiconductor substrate of the present invention may further include an element isolation film formation step, an interlayer insulating film planarization step, a metal wiring formation step, etc., in addition to the step of producing a silicon wafer.

[Rinsing Method]

A method for rinsing a silicon wafer of the present invention (hereinafter, also referred to as a “rinsing method of the present invention”) includes a rinsing step of subjecting a polished silicon wafer to a rinsing treatment using the rinsing composition of the present invention. The rinsing step in the rinsing method of the present invention can be carried out in the same manner as the rinsing step in the production method of a silicon wafer of the present invention and that in the production method of a semiconductor substrate of the present invention. In the rinsing method of the present invention, since the rinsing composition of the present invention is used in the rinsing step, it is possible to significantly reduce the amount of abrasive grains remaining on the polished silicon wafer while preventing the aggregation of abrasive grains, thereby shortening the washing time of the silicon wafer after rinsing and reducing the LPD.

The present invention further relates to the following compositions and production methods.

[1] A rinsing composition for a silicon wafer, containing a water-soluble polymer and an aqueous medium,

wherein the water-soluble polymer exhibits a difference (Z−Z₀) between a zeta-potential Z of a water-soluble polymer-containing silica aqueous dispersion (aqueous dispersion S) and a zeta-potential Z₀ of a silica aqueous dispersion (aqueous dispersion S₀) of 25 mV or less,
where the aqueous dispersion S consists of the water-soluble polymer, silica particles, water, and as needed, hydrochloric acid or ammonia, and has a concentration of the water soluble polymer of 0.1 mass %, a concentration of the silica particles of 0.1 mass %, and a pH of 7.0 at 25° C., and
the aqueous dispersion S₀ consists of silica particles, water, and as needed, hydrochloric acid or ammonia, and has a concentration of the silica particles of 0.1 mass %, and a pH of 7.0 at 25° C.

[2] A rinsing composition for a silicon wafer, containing a water-soluble polymer and an aqueous medium,

wherein the water-soluble polymer contains at least one selected from the group consisting of polyglycerin, polyglycerin derivative, polyglycidol, polyglycidol derivative, polyvinyl alcohol derivative, and polyacrylamide.

[3] The rinsing composition for a silicon wafer according to [1], wherein the difference (Z−Z₀) is preferably 15 mV or less, more preferably 9 mV or less, and further preferably 7 mV or less.

[4] The rinsing composition for a silicon wafer according to [1] or [3], wherein the water-soluble polymer has a ratio (d/d₀) of a secondary particle diameter d of the silica particles in the aqueous dispersion S to a secondary particle diameter d₀ of the silica particles in the aqueous dispersion S₀ of preferably 1.35 or less, more preferably 1.17 or less, further preferably 1.10 or less, and still further preferably 1.08 or less, while the ratio (d/d₀) is preferably 1.00 or more, more preferably 1.02 or more, further preferably 1.04 or more, and still further preferably 1.05 or more.

[5] The rinsing composition for a silicon wafer according to any of [1], [3] and [4], wherein the water-soluble polymer is preferably at least one selected from the group consisting of polyglycerin, polyglycerin derivative, polyglycidol, polyglycidol derivative, polyvinyl alcohol derivative, and polyacrylamide.

[6] The rinsing composition for a silicon wafer according to [2] or [5], wherein the polyglycerin derivative is preferably a polyglycerin derivative obtained by adding a functional group to polyglycerin via ether linkage or ester linkage, and more preferably a polyglycerin derivative obtained by adding a functional group to polyglycerin via ether linkage.

[7] The rinsing composition for a silicon wafer according to [5], wherein the polyglycerin derivative is preferably polyglycerin alkyl ether.

[8] The rinsing composition for a silicon wafer according to any of [1] to [4], wherein the water-soluble polymer is preferably at least one selected from the group consisting of polyglycerin, polyglycerin alkyl ether, polyglycerin dialkyl ether, polyglycerin fatty acid ester, polyethylene oxide-modified polyvinyl alcohol, sulfonic acid-modified polyvinyl alcohol, and polyacrylamide, and more preferably polyglycerin alkyl ether.

[9] The rinsing composition for a silicon wafer according to any of [1] to [4], wherein the water-soluble polymer preferably contains both of polyglycerin and polyglycerin alkyl ether.

[10] The rinsing composition for a silicon wafer according to any of [2] and [5] to [7], wherein the number of carbon atoms of the hydrophobic group of the polyglycerin derivative is preferably 6 or more, and more preferably 8 or more, and preferably 22 or less, and more preferably 18 or less.

[11] The rinsing composition for a silicon wafer according to [9], wherein the mass ratio (polyglycerin/polyglycerin alkyl ether) is preferably 0.5 or more, more preferably 1.0 or more, and further preferably 2.0 or more, and preferably 10 or less, more preferably 6.0 or less, and further preferably 5.0 or less.

[12] The rinsing composition for a silicon wafer according to any of [2] and [5] to [11], wherein the weight average molecular weight of the water-soluble polymer is preferably 500 or more, more preferably 700 or more, and further preferably 900 or more, and preferably 1,500,000 or less, more preferably 500,000 or less, further preferably 100,000 or less, still further preferably 25,000 or less, and yet further preferably 10,000 or less.

[13] The rinsing composition for a silicon wafer according to any of [2] and [5] to [12], wherein water-soluble polymer is made up of preferably 5 or more monomer units, more preferably 10 or more monomer units, and further preferably 15 or more monomer units, and preferably 5,000 or less monomer units, more preferably 500 or less monomer units, further preferably 200 or less monomer units, still further preferably 150 or less monomer units, and yet further preferably 100 or less monomer units.

[14] The rinsing composition for a silicon wafer according to any of [1] to [13], wherein the content of the water-soluble polymer in the rinsing composition is preferably 0.001 mass % or more, more preferably 0.015 mass % or more, further preferably 0.020 mass % or more, still further preferably 0.025 mass % or more, and yet further preferably 0.03 mass % or more, and preferably 1.0 mass % or less, more preferably 0.7 mass % or less, further preferably 0.4 mass % or less, still further preferably 0.1 mass % or less, and yet further preferably 0.08 mass % or less.

[15] The rinsing composition for a silicon wafer according to [1], wherein the water-soluble polymer is a mixture of at least one water-soluble polymer a1 selected from the group consisting of polyglycerin, polyglycerin derivative, polyglycidol, polyglycidol derivative, polyvinyl alcohol derivative and polyacrylamide, and a water-soluble polymer a2 having a betaine structure.

[16] The rinsing composition for a silicon wafer according to [15], wherein the water-soluble polymer is a mixture of polyglycerin alkyl ether and the water-soluble polymer a2 having a betaine structure.

[17] The rinsing composition for a silicon wafer according to [15] or [16], wherein the difference (Z−Z₀) is preferably 15 mV or less, more preferably 12 mV or less, and further preferably 9 mV or less.

[18] The rinsing composition for a silicon wafer according to any of [15] to [17], wherein the water-soluble polymer has a ratio (d/d₀) of the secondary particle diameter d of the silica particles in the aqueous dispersion S to the secondary particle diameter d₀ of the silica particles in the aqueous dispersion S₀ of preferably 1.35 or less, more preferably 1.34 or less, further preferably 1.33 or less, and still further preferably 1.32 or less, while the ratio (d/d₀) is preferably 1.00 or more, more preferably 1.25 or more, further preferably 1.30 or more, and still further preferably 1.31 or more.

[19] The rinsing composition for a silicon wafer according to any of [15] to [18], wherein the content of the water-soluble polymer a2 in the rinsing composition is preferably 0.00001 mass % or more, more preferably 0.00005 mass % or more, and further preferably 0.0001 mass % or more, and preferably 10 mass % or less, more preferably 5 mass % or less, and further preferably 1 mass % or less.

[20] The rinsing composition for a silicon wafer according to any of [15] to [19], wherein a mass ratio of the water-soluble polymer a1 to the water-soluble polymer a2 (the water-soluble polymer a1/the water-soluble polymer a2) is preferably 0.5 or more, more preferably 1 or more, and further preferably 2 or more, and preferably 500 or less, more preferably 200 or less, and further preferably 100 or less.

[21] The rinsing composition for a silicon wafer according to any of [15] to [20], wherein the water-soluble polymer a2 contains a constitutional unit A expressed by Formula (1) below.

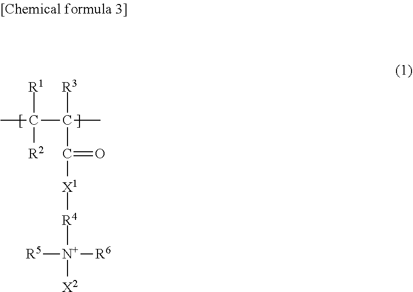

In Formula (1) above,

R¹ to R³ are the same or different and represent a hydrogen atom, a methyl group or an ethyl group,

R⁴ is an alkylene group with 1 to 4 carbon atoms or —Y¹—OPO₃⁻—Y²—,

Y¹ and Y² are the same or different and represent an alkylene group with 1 to 4 carbon atoms,

R⁵ and R⁶ are the same or different and represent a hydrocarbon group with 1 to 4 carbon atoms,

X¹ is O or NR⁷,

R⁷ is a hydrogen atom or a hydrocarbon group with 1 to 4 carbon atoms,

X² is a hydrocarbon group with 1 to 4 carbon atoms, —R¹⁷SO₃⁻ or —R¹⁸COO⁻, and

R¹⁷ and R¹⁸ are the same or different and represent an alkylene group with 1 to 4 carbon atoms.

When R⁴ is an alkylene group with 1 to 4 carbon atom, X² is —R¹⁷SO₃⁻ or —R¹⁸COO⁻. When R⁴ is —Y¹—OPO₃⁻Y²—, X² is a hydrocarbon group with 1 to 4 carbon atoms.

[22] The rinsing composition for a silicon wafer according to [21], wherein the water-soluble polymer a2 contains a constitutional unit B expressed by Formula (2) below.

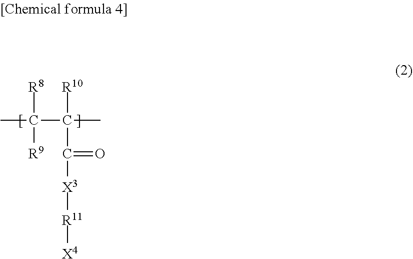

In Formula (2) above,

R⁸ to R¹⁰ are the same or different and represent a hydrogen atom, a methyl group or an ethyl group,

X³ is O or NR¹⁹,

R¹⁹ is a hydrogen atom or a hydrocarbon group with 1 to 4 carbon atoms,

R¹¹ is an alkylene group with 1 to 22 carbon atoms (the hydrogen atom of the alkylene group may be substituted with a hydroxyl group) or -(AO)ₘ-(where AO represents an alkyleneoxy group with 2 to 4 carbon atoms, and m represents an average number of added moles of 1 to 150),

X⁴ is a hydrogen atom, a hydrocarbon group with 1 to 4 carbon atoms (the hydrogen atom of the hydrocarbon group may be substituted with a hydroxyl group), a hydroxyl group, N⁺R¹²R¹³R¹⁴ or NR¹⁵R¹⁶, and

R¹² to R¹⁶ are the same or different and represent a hydrogen atom or a hydrocarbon group with 1 to 4 carbon atoms.

[23] The rinsing composition for a silicon wafer according to [22], wherein the mole ratio of the constitutional unit A to the constitutional unit B (the constitutional unit A/the constitutional unit B) in the water-soluble polymer a2 is preferably 10/90 or more, more preferably 20/80 or more, and further preferably 30/70 or more, and preferably 98/2 or less, and more preferably 95/5 or less.

[24] The rinsing composition for a silicon wafer according to any of [1] to [23], further containing a basic compound.

[25] The rinsing composition for a silicon wafer according to any of [1] to [24], wherein the pH of the rinsing composition at 25° C. is preferably 2 or more, more preferably 2.5 or more, and further preferably 3.0 or more, and preferably 12 or less, more preferably 11.5 or less, and further preferably 11.0 or less.

[26] The rinsing composition for a silicon wafer according to any of [1] and [3] to [25], wherein the rinsing composition for a silicon wafer is used for a silicon wafer that has been polished using a polishing liquid composition containing silica particles and a water-soluble polymer, and

the silica particles used for the preparation of the aqueous dispersion S and the aqueous dispersion S₀ are the same as the silica particles contained in the polishing liquid composition.

[27] A method for rinsing a silicon wafer, including a step of rinsing a polished silicon wafer using the rinsing composition according to any of [1] to [26].

[28] A method for producing a semiconductor substrate, including a step of rinsing a polished silicon wafer using the rinsing composition according to any of [1] to [26].

[29] A method for producing a semiconductor substrate, including:

a polishing step of polishing a silicon wafer to be polished using a polishing liquid composition that contains silica particles and a water-soluble polymer;

a rinsing step of rinsing the polished silicon wafer using the rinsing composition according to any of [1] to [26]; and

a washing step of washing the rinsed silicon wafer,

wherein the silica particles used for the preparation of the aqueous dispersion S and the aqueous dispersion S₀ are the same as the silica particles contained in the polishing liquid composition.

[30] The method for producing a semiconductor substrate according to [29], wherein the polishing step is preferably a rough polishing step of planarizing a silicon wafer that has been obtained by slicing a silicon single crystal ingot into thin disks, or a final polishing step of etching the lapped silicon wafer and mirror-finishing the surfaces of the silicon wafer, and more preferably the final polishing step.

[31] A method for producing a silicon wafer, including:

a polishing step of polishing a silicon wafer to be polished using a polishing liquid composition that contains silica particles, a water-soluble polymer B (where the water-soluble polymer contained in the rinsing composition according to any of [1] to [26] is referred to as a water-soluble polymer A), a nitrogen-containing basic compound, and an aqueous medium;

a rinsing step of subjecting the polished silicon wafer to a rinsing treatment using the rinsing composition according to any of [1] to [26]; and

a washing step of washing the rinsed silicon wafer.

[32] The method for producing a silicon wafer according to [31],

wherein the water-soluble polymer B exhibits a difference (z−z₀) between a zeta-potential z of a water-soluble polymer-containing silica aqueous dispersion (aqueous dispersion s) and a zeta-potential z₀ of a silica aqueous dispersion (aqueous dispersion s₀) of 15 mV or more,
where the aqueous dispersion s consists of the water-soluble polymer, silica particles, water, and as needed, hydrochloric acid or ammonia, and has a concentration of the water-soluble polymer of 0.01 mass %, a concentration of the silica particles of 0.1 mass %, and a pH of 10.0 at 25° C., and
the aqueous dispersion s₀ consists of silica particles, water, and as needed, hydrochloric acid or ammonia, and has a concentration of the silica particles of 0.1 mass %, and a pH of 10.0 at 25° C.

[33] The method for producing a silicon wafer according to [32], wherein the water-soluble polymer B has a ratio (D/D₀) of a secondary particle diameter D of the silica particles in the aqueous dispersion s to a secondary particle diameter D₀ of the silica particles in the aqueous dispersion s₀ of 1.10 or more.

[34] The method for producing a silicon wafer according to any of [31] to [33], wherein the water-soluble polymer B is at least one selected from the group consisting of polysaccharide, alkyl acrylamide-based polymer, polyvinyl alcohol, and polyvinyl alcohol derivative (except for anion-modified polyvinyl alcohol).

[35] The method for producing a silicon wafer according to any of [31] to [34],

wherein the water-soluble polymer B is hydroxyethyl cellulose, and

the water-soluble polymer A is a polyglycerin derivative.

[36] The method for producing a silicon wafer according to any of [31] to [35], wherein in the rinsing step, a water rinsing treatment using water as a rinsing agent is carried out prior to the rinsing treatment.

[37] The method for producing a silicon wafer according to any of [31] to [36], wherein the rinsing treatment in the rinsing step is carried out by a polishing machine used in the polishing step.

[38] A method for producing a semiconductor substrate including a step of producing a silicon wafer by the method for producing a silicon wafer according to any of [31] to [37].

### EXAMPLES

1. Measurement Method of Various Parameters

(1) Measurement method of zeta-potentials of aqueous dispersions S₀, S, s₀ and s

Each aqueous dispersion was placed in a capillary cell DTS1070 to measure the zeta-potential using “Zetasizer Nano ZS” manufactured by Malvern Panalytical Ltd., under the conditions below.

Sample: refractive index: 1.450, absorptance: 0.010

Dispersion medium: viscosity: 0.8872 cP, refractive index: 1.330, dielectric constant: 78.5

Temperature: 25° C.

(1-1) Preparation of Silica Aqueous Dispersion (Aqueous Dispersion S₀)

Ion exchanged water was added to a silica particle stock solution (“PL-3” manufactured by FUSO CHEMICAL CO., LTD), and a hydrochloric acid aqueous solution or an ammonia aqueous solution was added thereto to adjust the pH at 25° C. to 7.0, whereby the aqueous dispersion S₀ having a concentration of the silica particles of 0.1 mass % was obtained.

(1-2) Preparation of Water-Soluble Polymer-Containing Silica Aqueous Dispersion (Aqueous Dispersion S)

The water-soluble polymer A was added to ion exchanged water, and a silica particle stock solution (“PL-3” manufactured by FUSO CHEMICAL CO., LTD) was added thereto. Then, a hydrochloric acid aqueous solution or an ammonia aqueous solution was added thereto to adjust the pH at 25° C. to 7.0, whereby the aqueous dispersion S having a concentration of the water-soluble polymer of 0.1 mass % and a concentration of the silica particles of 0.1 mass % was obtained.

(2-1) Preparation of Silica Aqueous Dispersion (Aqueous Dispersion s₀)

Ion exchanged water was added to a silica particle stock solution (“PL-3” manufactured by FUSO CHEMICAL CO., LTD), and a hydrochloric acid aqueous solution or an ammonia aqueous solution was added thereto to adjust the pH at 25° C. to 10.0, whereby the aqueous dispersion s₀ having a concentration of the silica particles of 0.1 mass % was obtained.

(2-2) Preparation of Water-Soluble Polymer-Containing Silica Aqueous Dispersion (Aqueous Dispersion s)

The water-soluble polymer B was added to ion exchanged water, and a silica particle stock solution (“PL-3” manufactured by FUSO CHEMICAL CO., LTD.) was added thereto. Then, a hydrochloric acid aqueous solution or an ammonia aqueous solution was added thereto to adjust the pH at 25° C. to 10.0, whereby the aqueous dispersion S having a concentration of the water-soluble polymer of 0.01 mass % and a concentration of the silica particles of 0.1 mass % was obtained.

(2) Measurement Method of Secondary Particle Diameter of Silica Particles

Each of the silica aqueous dispersions S₀, S, s₀, and s was poured into a disposable sizing cuvette (a 10 mm cell made of polystyrene) up to the height of 10 mm from the bottom and measured by a dynamic light scattering method using “Zetasizer Nano ZS” manufactured by Malvern Panalytical Ltd. The measured Z average particle diameters were determined as the secondary particle diameters d₀, d, D₀, and D of the silica aqueous dispersions S₀, S, s₀, and s, respectively. The following are the measurement conditions.

Sample: refractive index: 1.450, absorptance: 0.010

Dispersion medium: viscosity: 0.8872 cP, refractive index: 1.330

Temperature: 25° C.

(3) Measurement of Weight Average Molecular Weight of Water-Soluble Polymer

The weight average molecular weight of the water-soluble polymer A used for the preparation of the rinsing composition and the weight average molecular weight of the water-soluble polymer B used for the preparation of the polishing liquid composition were calculated based on the peak in chromatogram obtained by applying a gel permeation chromatography (GPC) method under the conditions below.

Instrument: HLC-8320 GPC (manufactured by TOSOH CORPORATION, detector integral type)

Column: GMPWXL+GMPWXL (anion)

Eluant: 0.2 M phosphoric acid buffer/CH₃CN=9/1

Flow rate: 0.5 mL/min

Column temperature: 40° C.

Detector: RI detector

Reference material: monodispersed polyethylene glycol of known weight average molecular weight

2. Preparation of Rinsing Compositions

Rinsing compositions (all concentrates) of Examples 1-17 and Comparative Examples 1-5 were prepared by stirring and mixing the corresponding water-soluble polymer A and ion exchanged water indicated in Tables 1 and 2, and adjusting the pH at 25° C. to 7.0 using a hydrochloric acid aqueous solution or 28 mass % ammonia water (special grade reagent manufactured by Kishida Chemical Co., Ltd.) as needed. The exceptions were that the pH was adjusted to 4.0 in Example 9, the pH was adjusted to 10.0 in Example 10, and the concentration of ammonia was set to 5 ppm in Comparative Example 5. A remainder after subtracting the water-soluble polymer and hydrochloric acid or ammonia was ion exchanged water. Incidentally, the contents of the respective components in Table 1 are values of the rinsing compositions obtained by diluting the concentrates by 20 times. Rinsing compositions (all concentrates) of Examples 18-27 and Comparative Example 6 were prepared to have a pH at 25° C. of 7.0 and a content of the water-soluble polymer A of 0.05 mass % when diluted by 20 times. The exceptions were that in Examples 25-27, the content of polyglycerin alkyl ether was 0.049 mass %, and the content of the water-soluble polymer having a betaine structure was 0.001 mass %.

The following are the details of the water-soluble polymers used for the preparation of the rinsing compositions of Examples 1-27 and Comparative Examples 1-6 and the water-soluble polymers used for the preparation of the polishing compositions of Examples 18-27 and Comparative Example 6.

A1: PGL 20PW (polyglycerin made up of 20 monomer units): manufactured by Daicel Corporation

A2: PGL XPW (polyglycerin made up of 40 monomer units): manufactured by Daicel Corporation

A3: PGL 100PW (polyglycerin made up of 100 monomer units): manufactured by Daicel Corporation

A4: CELMOLLIS B044 (polyglyceryl-20 lauryl ether): manufactured by Daicel Corporation

A5: Polyacrylamide (Mw 10,000): manufactured by Polysciences, Inc.

A6: Polyacrylamide (Mw 600,000 to 1,000,000): manufactured by Polysciences, Inc.

A7: GOHSERAN L-3266 (Mw 23,000): manufactured by The Nippon Synthetic Chemical Industry Co., Ltd.

A8: Kollicoat (registered trademark) IR (Mw 26,500): manufactured by BASF SE

A9: Lipidure-HM (Mw 100,000): manufactured by NOF CORPORATION

A10: Lipidure-PMB (Mw 600,000, mole ratio (MPC/BMA)=80:20): manufactured by NOF CORPORATION

A11: MPC/LMA (Mw 100,000): manufactured by Kao Corporation

A51: Poly(N-isopropylacrylamide) (Mn 20,000˜40,000): manufactured by MERCK KGAA, DARMSTAIDT (SIGMA-ALDRICH)

A52: SE400 (Mw 250,000): manufactured by Daicel Corporation

A53: PVA-117 (Mw 75,000): manufactured by KURARAY CO., LTD.

A54 Poly(ethylene oaxide) (Mw 200,000): manufactured by Polysciences, Inc.

A55: n-Decylpentaoxyethylene: manufactured by Bachem AG

A56: Polyhydroxyethyl acrylamide (Mw 700,000)

Table 3 shows the details of the constitutional units of the water-soluble polymers A9-A11. The synthesis method of the water-soluble polymer A11 is as below.

[Water-Soluble Polymer a11]

10.0 g of ethanol was placed in a four-neck flask (capacity: 300 mL) and heated to 70° C. A solution obtained by mixing 5.0 g of MPC (manufactured by Tokyo Chemical Industry Co., Ltd.), 1.1 g of LMA (manufactured by FUJIFILM Wako Pure Chemical Corporation) and 10.0 g of ethanol, and a solution obtained by mixing 0.021 g of 2,2′-azobis(isobutyronitrile) (manufactured by FUJIFILM Wako Pure Chemical Corporation) and 4.4 g of ethanol were separately dropped into the flask for two hours for polymerization. After six hours of aging, the solvent was distilled off under reduced pressure and replaced with water, whereby a polymer aqueous solution containing the water-soluble polymer A11 (a copolymer of MPC and LMA) was obtained. The mole ratio (MPC/LMA) of the constitutional units in the water-soluble polymer A11 was 80/20, and the weight average molecular weight of the water-soluble polymer A11 was 100,000.

3. Rinsing Method

Each rinsing composition (concentrate) was diluted by 20 times with ion-exchanged water. The rinsing composition diluted was filtered with a filter (compact cartridge filter “MCP-LX-C10S” manufactured by Advantech Co., Ltd.) immediately before the start of the rinsing treatment, and silicon wafers described below (silicon single-sided mirror wafer 200 mm in diameter (conduction type: P, crystal orientation: 100, resistivity: 0.1 Ω·cm or more and less than 100 Ω·cm)) were subjected to a rinsing treatment under the rinsing conditions below. In advance of the rinsing treatment, the silicon wafers were roughly polished using a commercially available polishing composition. The silicon wafers that had been roughly polished and subjected to a final polishing had a surface roughness (haze) of 2.680 (ppm). The haze is a value at the dark field wide oblique incidence channel (DWO) measured using “Surfscan SP1-DIS” manufactured by KLA Corporation. The silicon wafers were then subjected to a final polishing under the conditions below and subjected to a rinsing treatment using the respective rinsing compositions directly after the final polishing, under the conditions below.

[Polishing Composition Used in Final Polishing]

The polishing composition used in the final polishing, which was carried out before the rinsing step using the rinsing compositions of Examples 1-17 and Comparative Examples 1-5, was obtained in the following manner. SE-400 (manufactured by Daicel Corporation, HEC, molecular weight: 250,000), PEG 6000 (manufactured by FUJIFILM Wako Pure Chemical Corporation, Wako 1st Grade), ammonia water (manufactured by Kishida Chemical Co., Ltd., special grade reagent), PL-3 (manufactured by FUSO CHEMICAL CO., LTD) and ion exchanged water were stirred and mixed to obtain a concentrate, and then the concentrate was diluted by 40 times with ion exchanged water immediately before use. The following is the composition of the polishing composition used in the final polishing.

Silica particles (PL-3, average primary particle diameter: 35 nm, average secondary particle diameter: 69 nm, degree of association: 2.0): 0.17 mass %

HEC (SE-400): 0.01 mass %

Ammonia: 0.01 mass %

PEG (weight average molecular weight: 6000): 0.0008 mass %

The following are the compositions of the polishing liquid compositions of Examples 18-27 and Comparative Example 6 indicated in Table 2.

Silica particles (PL-3, average primary particle diameter: 35 nm, average secondary particle diameter: 69 nm, degree of association: 2.0): 0.17 mass %

Water-soluble polymer B: 0.01 mass %

Ammonia: 0.01 mass %

PEG (weight average molecular weight: 6000): 0.0008 mass %

[Final Polishing Conditions]

Polishing machine: a single-sided 8-inches polishing machine “GRIND-X SPP600s” (manufactured by Okamoto Machine Tool Works, Ltd.)

Polishing pad: suede pad (manufactured by Toray Coatex Co., Ltd., ASKER hardness: 64, thickness: 1.37 mm, nap length: 450 μm, opening diameter: 60 μm)

Silicon wafer polishing pressure: 100 g/cm²

Number of rotary table revolutions: 60 rpm

Polishing time: 5 minutes

Polishing composition supply rate: 150 g/min

Temperature of polishing composition: 23° C.

Carrier rotation rate: 60 rpm

[Rinsing Conditions]

Polishing machine: a single-sided 8-inches polishing machine “GRIND-X SPP600s” (manufactured by Okamoto Machine Tool Works, Ltd.)

Polishing pad: suede pad (manufactured by Toray Coatex Co., Ltd., ASKER hardness: 64, thickness: 1.37 mm, nap length: 450 μm, opening diameter: 60 μm)

Silicon wafer rinsing pressure: 60 g/cm²

Number of rotary table revolutions: 30 rpm

Rinsing time: 10 seconds

Rinsing composition supply rate: 1000 mL/min

Temperature of rinsing composition: 23° C.

Carrier rotation rate: 30 rpm

4. Washing Method

After the rinsing treatment, the silicon wafer was subjected to washing with ozone and washing with dilute hydrofluoric acid as described below. In the washing with ozone, an aqueous solution containing 20 ppm of ozone was jetted at a flow rate of 1 L/min. for 3 minutes from a nozzle toward the center of a silicon wafer rotating at 600 rpm. At this time, the temperature of the ozone water was set to a room temperature. Next, washing with dilute hydrofluoric acid was carried out. In the washing with dilute hydrofluoric acid, an aqueous solution containing 0.5 mass % of ammonium hydrogen fluoride (special grade: Nakalai Tesque, Inc.) was jetted at a flow rate of 1 L/min. for 5 seconds from a nozzle toward the center of the silicon wafer rotating at 600 rpm. The set of one washing with ozone and one washing with dilute hydrofluoric acid was carried out twice, which was followed by a final spin drying. In the spin drying, the silicon wafer was rotated at 1500 rpm.

5. Evaluation of Surface Defects (LPD) of Silicon Wafer

The LPD of the silicon wafer surfaces after washing was evaluated by measuring the number of particles having a particle diameter of 45 nm or more on the silicon wafer surfaces using a surface roughness measuring device “Surfscan SP1-DLS” (manufactured by KLA Corporation). The evaluation results of the LPD indicates that the smaller the value, the less the surface defects. Two silicon wafers were used for each LPD measurement. Tables 1 and 2 indicate the average values.

6. Evaluation of Polishing Rate

The polishing rate was evaluated in the following manner. The weights of each silicon wafer before and after polishing were measured using a precise balance (“BP-210S” manufactured by Sartorius). The obtained weight difference was divided by the density and area of the silicon wafer and the polishing time so as to calculate the single-side polishing rate per unit time. The results are indicated in Table 2 as relative values where the polishing rate of Comparative Example 6 is set to 1.00.

TABLE 1

| | | Water-soluble polymer A | | | | | | | | |
|---|---|---|---|---|---|---|---|---|---|---|
| | | | | | | Potential | | | | |
| | | | | | | difference | | | | |
| | | | | Concentration | Potential Z*² | (Z − Z₀*³) | d*⁵ | d₀*⁴ | Ratio | LPD |
| | | Type | | (mass %) | (mV) | (mV) | (nm) | (nm) | (d/d₀) | (number) |
| Ex. | 1 | A1 | Polyglycerin (20 monomer units) | 0.05 | −44.5 | 1.6 | 70.8 | 68.4 | 1.04 | 142 |
| | 2 | A2 | Polyglycerin (40 monomer units) | 0.05 | −44.2 | 1.9 | 71 | 68.4 | 1.04 | 120 |
| | 3 | A3 | Polyglycerin(100 monomer units) | 0.05 | −43.5 | 2.6 | 71.2 | 68.4 | 1.04 | 118 |
| | 4 | A4 | Polyglycerin alkyl ether | 0.001 | −40.6 | 5.5 | 71.9 | 68.4 | 1.05 | 183 |
| | 5 | | | 0.01 | | | | | | 146 |
| | 6 | | | 0.05 | | | | | | 107 |
| | 7 | | | 0.1 | | | | | | 118 |
| | 8 | | | 0.5 | | | | | | 142 |
| | 9 | | | 0.05 | | | | | | 108 |
| | 10 | | | 0.05 | | | | | | 112 |
| | 11 | A2 + A4 | Polyglycerin (40 monomer units) + | 0.05*¹ | −41.2 | 4.9 | 72 | 68.4 | 1.05 | 97 |
| | | | Polyglycerin alkyl ether | | | | | | | |
| | 12 | A5 | Polyacrylamide (Mw 10,000) | 0.05 | −38.7 | 7.4 | 69.1 | 68.4 | 1.01 | 136 |
| | 13 | A6 | Polyacrylamide (Mw 600,000 to 1,000,000) | 0.05 | −27.9 | 18.2 | 76.1 | 68.4 | 1.11 | 126 |
| | 14 | A7 | Sulfonic acid-modified polyvinyl alcohol | 0.05 | −36.9 | 9.2 | 74.6 | 68.4 | 1.09 | 125 |
| | 15 | A4 + A9 | Polyglycerin alkyl ether + MPC homopolymer | 0.05*⁷ | −39.9 | 6.2 | 84.3 | 68.4 | 1.23 | 102 |
| | 16 | A4 + A10 | Polyglycerin alkyl ether + MPC/BMA | 0.05*⁷ | −39.1 | 7.0 | 89.5 | 68.4 | 1.31 | 87 |
| | 17 | A4 + A11 | Polyglycerin alkyl ether + MPC/LMA | 0.05*⁷ | −37.7 | 8.4 | 90.1 | 68.4 | 1.32 | 83 |
| Comp. | 1 | A51 | pNIPAM | 0.018 | −20.2 | 25.9 | 190.9 | 68.4 | 2.79 | 253 |
| Ex. | 2 | A52 | HEC (Mw 250,000) | 0.0125 | −9.6 | 36.5 | 171.7 | 68.4 | 2.51 | 229 |
| | 3 | A53 | PVA (Mw 75,000) | 0.0125 | −13.3 | 32.8 | 94.1 | 68.4 | 1.38 | 246 |
| | 4 | A54 | PEG (Mw 200,000) | 0.0125 | −6.3 | 39.8 | 113.1 | 68.4 | 1.65 | 4520 |
| | 5 | A52 +A55 | HEC (Mw 250,000) + POE(5) | 0.01*⁶ | −10.8 | 35.3 | 170.4 | 68.4 | 2.49 | 191 |
| | | | decyl ether (5 ppm) | | | | | | | |

*¹Polyglycerin (0.04 mass %) + Polyglycerin alkyl ether (0.01 mass %)
*²Z represents a zeta-potential of a water-soluble polymer-containing silica aqueous dispersion (aqueous dispersion S) containing 0.1 mass % of a water-soluble polymer and 0.1 mass % of silica particles and having a pH of 7.0.
*³Z₀ represents a zeta-potential of a silica aqueous dispersion (aqueous dispersion S₀) containing 0.1 mass % of silica particles and having a pH of 7.0.
*⁴d₀ represents a secondary particle diameter of the silica particles in the aqueous dispersion S₀.
*⁵d represents a secondary particle diameter of the silica particles in the aqueous dispersion S.
*⁶POE(5) decyl ether (5 mass ppm), remainder is HEC (Mw 250,000)
*⁷Polyglycerin alkyl ether (0.049 mass %) + Water-soluble polymer having a betaine structure (0.001 mass %)

As shown in Table 1, the rinsing compositions of Examples 1-17 reduced the number of the LPD more favorably than the rinsing compositions of Comparative Examples 1-5. Therefore, the rinsing compositions of Examples 1-17 can shorten the washing time as compared with the rinsing compositions of Comparative Examples 1-5.

TABLE 2

| | | Polishing liquid composition | | | | Rinsing composition | | | | | |
|---|---|---|---|---|---|---|---|---|---|---|---|
| | | | | Potential | | | | Potential | | Polishing | |
| | | | | difference | | | | difference | | rate | |
| | | Water-soluble | | (z*¹ − z₀*²) | Ratio | | | (Z*⁵ − Z₀*⁶) | Ratio | (relative | LPD |
| | | polymer B | | (mV) | (D*⁴/D₀*³) | Water-soluble polymer A | | (mV) | (d*⁸/d₀*⁷) | value) | (number) |
| Ex. | 18 | A56 | pHEAA | 44 | 1.56 | A4 | Polyglycerin | 5.5 | 1.05 | 1.26 | 114 |
| | 19 | A53 | PVA | 27.9 | 1.15 | | alkyl ether | | 1.05 | 0.61 | 135 |
| | | | (Mw 75,000) | | | | | | | | |
| | 20 | A8 | PEG-g-PVA | 20.5 | 1.18 | | | | 1.05 | 0.56 | 104 |
| | 21 | A52 | HEC | 39.9 | 1.48 | A2 | Polyglycerin | 1.9 | 1.04 | 1.00 | 120 |
| | | | | | | | (40 monomer units) | | | | |
| | 22 | | (Mw 250,000) | | | A4 | Polyglycerin | 5.5 | 1.05 | 1.00 | 107 |
| | | | | | | | alkyl ether | | | | |
| | 23 | | | | | A6 | Polyacrylamide | 18.2 | 1.11 | 1.00 | 126 |
| | | | | | | | (Mw 600,000 to | | | | |
| | | | | | | | 1,000,000) | | | | |
| | 24 | | | | | A7 | Sulfonic acid- | 9.2 | 1.09 | 1.00 | 125 |
| | | | | | | | modified polyvinyl | | | | |
| | | | | | | | alcohol | | | | |
| | 25 | | | | | A4 + A9 | Polyglycerin alkyl | 6.2 | 1.23 | 1.00 | 102 |
| | | | | | | | ether + MPC | | | | |
| | | | | | | | homopolymer | | | | |
| | 26 | | | | | A4 + A10 | Polyglycerin alkyl | 7.0 | 1.31 | 1.00 | 87 |
| | | | | | | | ether + MPC/BMA | | | | |
| | 27 | | | | | A4 + A11 | Polyglycerin alkyl | 8.4 | 1.32 | 1.00 | 83 |
| | | | | | | | ether + MPC/BMA | | | | |
| Comp. | 6 | A52 | HEC | 39.9 | 1.48 | A52 | HEC (Mw 250,000) | 36.5 | 2.51 | 1.00 | 229 |
| Ex. | | | (Mw 250,000) | | | | | | | | |

*¹z represents a zeta-potential of a water-soluble polymer-containing silica aqueous dispersion (aqueous dispersion s) containing 0.01 mass % of the water-soluble polymer B and 0.1 mass % of silica particles and having a pH of 10.0.
*²z₀ represents a zeta-potential of a silica aqueous dispersion (aqueous dispersion s₀) containing 0.1 mass % of silica particles and having a pH of 10.0.
*³D₀ represents a secondary particle diameter of the silica particles in the aqueous dispersion s₀.
*⁴D represents a secondary particle diameter of the silica particles in the aqueous dispersion s.
*⁵Z represents a zeta-potential of a water-soluble polymer-containing silica aqueous dispersion (aqueous dispersion S) containing 0.1 mass % of the water-soluble polymer A and 0.1 mass % of silica particles and having a pH of 7.0.
In Examples 25-27, Polyglycerin alkyl ether (0.098 mass %) + Water-soluble polymer having a betaine structure (0.002 mass %)
*⁶Z₀ represents a zeta-potential of a silica aqueous dispersion (aqueous dispersion S₀) containing 0.1 mass % of silica particles and having a pH of 7.0.
*⁷d₀ represents a secondary particle diameter of the silica particles in the aqueous dispersion S₀.
*⁸d represents a secondary particle diameter of the silica particles in the aqueous dispersion S.

As shown in Table 2, the rinsing compositions of Examples 18-27 each containing the water-soluble polymer A having the property of exhibiting the difference (Z−Z₀) of 25 mV or less can achieve both of the improvement in the polishing rate and the reduction of the LPD as compared with the rinsing composition of Comparative Example 6.

TABLE 3

| Constitu- | | |
|---|---|---|
| tional unit | Structure in Formula (1) | Structure in Formula (2) |
| BMA | — | R⁸═R⁹═H, R¹⁰═CH₃, |
| | | X³═O R¹¹═C₄H₈, |
| | | X⁴═H |
| MPC | R¹═R²═H, R³═CH₃, | — |
| | R⁴═—Y¹—OPO₃⁻—Y²—, | |
| | Y¹═Y²═C₂H₄, | |
| | R⁵═R⁶═CH₃, X¹═O, X²═CH₃ | |
| LMA | — | R⁸═R⁹═H, R¹⁰═CH₃, |
| | | X³═O R¹¹═C₁₂H₂₄, |
| | | X⁴═H |

### INDUSTRIAL APPLICABILITY

The rinsing composition of the present invention can shorten the washing time of silicon wafers, thereby contributing to the improvement in the productivity and cost reduction and being useful in the production of semiconductor substrates.

1. A rinsing composition for a silicon wafer, comprising a water-soluble polymer and an aqueous medium,
wherein the water-soluble polymer exhibits a difference (Z−Z₀) between a zeta-potential Z of a water-soluble polymer-containing silica aqueous dispersion (aqueous dispersion S) and a zeta-potential Z₀ of a silica aqueous dispersion (aqueous dispersion S₀) of 25 mV or less,
where the aqueous dispersion S consists of the water-soluble polymer, silica particles, water, and as needed, hydrochloric acid or ammonia, and has a concentration of the water-soluble polymer of 0.1 mass %, a concentration of the silica particles of 0.1 mass %, and a pH of 7.0 at 25° C., and
the aqueous dispersion S₀ consists of silica particles, water, and as needed, hydrochloric acid or ammonia, and has a concentration of the silica particles of 0.1 mass %, and a pH of 7.0 at 25° C.

2. A rinsing composition for a silicon wafer, comprising a water-soluble polymer and an aqueous medium,
wherein the water-soluble polymer comprises at least one selected from the group consisting of polyglycerin, polyglycerin derivative, polyglycidol, polyglycidol derivative, polyvinyl alcohol derivative, and polyacrylamide.

3. The rinsing composition for a silicon wafer according to claim 1, wherein the water-soluble polymer has a ratio (d/d₀) of a secondary particle diameter d of the silica particles in the aqueous dispersion S to a secondary particle diameter d₀ of the silica particles in the aqueous dispersion S₀ of 1.35 or less.

4. The rinsing composition for a silicon wafer according to claim 1, wherein the water-soluble polymer is at least one selected from the group consisting of polyglycerin, polyglycerin derivative, polyglycidol, polyglycidol derivative, polyvinyl alcohol derivative, and polyacrylamide.

5. The rinsing composition for a silicon wafer according to claim 4, wherein the polyglycerin derivative is polyglycerin alkyl ether.

6. The rinsing composition for a silicon wafer according to claim 1, further comprising a basic compound.

7. A method for rinsing a silicon wafer, comprising a step of rinsing a polished silicon wafer using the rinsing composition according to claim 1.

8. A method for producing a semiconductor substrate, comprising a step of rinsing a polished silicon wafer using the rinsing composition according to claim 1.

9. A method for producing a silicon wafer, comprising:
a polishing step of polishing a silicon wafer to be polished using a polishing liquid composition that comprises silica particles, a water-soluble polymer B (where the water-soluble polymer contained in the rinsing composition according to claim 1 is referred to as a water-soluble polymer A), a nitrogen-containing basic compound, and an aqueous medium;
a rinsing step of subjecting the polished silicon wafer to a rinsing treatment using the rinsing composition according to claim 1; and
a washing step of washing the rinsed silicon wafer.

10. The method for producing a silicon wafer according to claim 9,
wherein the water-soluble polymer B exhibits a difference (z−z₀) between a zeta-potential z of a water-soluble polymer-containing silica aqueous dispersion (aqueous dispersion s) and a zeta-potential z₀ of a silica aqueous dispersion (aqueous dispersion s₀) of 15 mV or more,
where the aqueous dispersion s consists of the water-soluble polymer B, silica particles, water, and as needed, hydrochloric acid or ammonia, and has a concentration of the water-soluble polymer B of 0.01 mass %, a concentration of the silica particles of 0.1 mass %, and a pH of 10.0 at 25° C., and
the aqueous dispersion s₀ consists of silica particles, water, and as needed, hydrochloric acid or ammonia, and has a concentration of the silica particles of 0.1 mass %, and a pH of 10.0 at 25° C.

11. The method for producing a silicon wafer according to claim 10, wherein the water-soluble polymer B has a ratio (D/D₀) of a secondary particle diameter D of the silica particles in the aqueous dispersion s to a secondary particle diameter D₀ of the silica particles in the aqueous dispersion s₀ of 1.10 or more.

12. The method for producing a silicon wafer according to claim 9, wherein the water-soluble polymer B is at least one selected from the group consisting of polysaccharide, alkyl acrylamide-based polymer, polyvinyl alcohol, and polyvinyl alcohol derivative (except for anion-modified polyvinyl alcohol).

13. The method for producing a silicon wafer according to claim 9,
wherein the water-soluble polymer B is hydroxyethyl cellulose, and
the water-soluble polymer A is a polyglycerin derivative.

14. The method for producing a silicon wafer according to claim 9, wherein in the rinsing step, a water rinsing treatment using water as a rinsing agent is carried out prior to the rinsing treatment.

15. The method for producing a silicon wafer according to claim 9, wherein the rinsing treatment in the rinsing step is carried out by a polishing machine used in the polishing step.

16. A method for producing a semiconductor substrate comprising a step of producing a silicon wafer by the method for producing a silicon wafer according to claim 9.
